(19) United States
(12) Patent Application Publication
(10) Pub. No.: US 2026/0298985 A1
(43) Pub. Date: Oct. 1, 2026

(54) NON-CONTACT MULTI-WIRE CURRENT MEASUREMENT SYSTEM

(71) Applicant: Huizhou City Fu Yi Electronic Technology Co., Ltd., Huizhou (CN)

(72) Inventors: Chenqin FU, Huizhou (CN); Haipeng FU, Huizhou (CN); Yuanhai FU, Huizhou (CN)

(73) Assignee: Huizhou City Fu Yi Electronic Technology Co., Ltd., Huizhou (CN)

(21) Appl. No.: 19/650,572

(22) Filed: Apr. 17, 2026

(30) Foreign Application Priority Data
Nov. 6, 2025 (CN) 202511616264.4

(51) Int. Cl. G01R 15/20; G01R 19/00

(52) U.S. Cl. CPC G01R 15/202; G01R 19/0092

(57) ABSTRACT

In a non-contact multi-wire current measurement system a live wire magnetic field signal and a neutral wire magnetic field signal are synchronously acquired in real time based on a preset sampling frequency, to achieve highly time-synchronized magnetic field acquisition without damaging a cable structure, avoiding a phase misalignment problem caused by a traditional clamp sensor under a multi-wire interference condition. A magnetic field amplitude ratio is calculated in real time, sensitivity is automatically adjusted based on a coupling deviation due to a difference in wire diameter and insulation layer, a self-corrected magnetic field signal set is generated, a live wire current and a neutral wire current are calculated, and a total current is obtained by further combining the live wire current with the neutral wire current. This non-contact vector-based calculation method avoids wire heating, voltage drop, and safety risks associated with direct series measurement.

### CROSS-REFERENCE TO RELATED APPLICATIONS

This application claims priority to Chinese Patent Application No. 202511616264.4 with a filing date of Nov. 6, 2025. The content of the aforementioned application, including any intervening amendments thereto, is incorporated herein by reference.

### TECHNICAL FIELD

The present disclosure relates to the field of current measuring technologies, and specifically, relates to a non-contact multi-wire current measurement system.

### BACKGROUND

In modern industry, smart grids, and efficient energy management, current measurement technology plays a crucial role. Especially in scenarios with a plurality of wires or electrical systems, precise current measurement is particularly important. However, a traditional current measurement method generally relies on a contact-based measurement technology or requires a destructive modification to a system during mounting, which significantly affects a service life and operational efficiency of an existing device. Therefore, a non-contact multi-wire current measurement system emerges, to monitor and measure currents without being in direct contact with a current-carrying conductor, offering significant advantages. Especially in high-density wiring and interference-prone environments, the non-contact multi-wire current measurement system can provide more stable and accurate data. The non-contact multi-wire current measurement system is configured to precisely capture and analyze magnetic fields generated by the currents and is widely used in fields such as power monitoring, smart homes, industrial automation, and electric vehicles.

Currently, the non-contact current measurement system still faces a common challenge in a complex electrical system, especially in multi-wire current measurement. Variations in magnetic field intensity and current coupling effects between wires may lead to systematic errors. Especially in measurement of live and neutral wires, magnetic field interference between the wires often affects accuracy and stability of measurement results. In the prior art, fixed sensitivity settings are generally used for magnetic field acquisition and current calculation. However, due to factors such as different wire layouts, wire diameters, and insulation thicknesses, these fixed settings cannot adapt to changes frequently encountered in practical applications. Consequently, a conventional non-contact multi-wire current measurement system is prone to error accumulation under different load conditions, environmental changes, or cable aging, potentially leading to device damage or safety hazards. The measurement sensitivity cannot be effectively and dynamically adjusted to adapt to these changes, resulting in measurement errors and poor device consistency.

### SUMMARY OF PRESENT INVENTION

To overcome the shortcomings in the prior art, the present disclosure provides a non-contact multi-wire current measurement system, to resolve the problems mentioned in the background art.

To achieve the above objectives, the present disclosure is realized through the following technical solutions: A non-contact multi-wire current measurement system is provided, including following modules:
a data acquisition module configured to perform real-time acquisition on a live wire magnetic field signal and a neutral wire magnetic field signal based on a preset sampling frequency;
a signal processing module configured to perform filtering and smoothing on the live wire magnetic field signal and the neutral wire magnetic field signal to obtain a processed re-labeled live wire magnetic field signal and a processed re-labeled neutral wire magnetic field signal;
a dynamic correction module configured to calculate a magnetic field amplitude ratio in real time based on the processed re-labeled live wire magnetic field signal and the processed re-labeled neutral wire magnetic field signal, dynamically adjust measurement sensitivity based on the magnetic field amplitude ratio, and then calculate a magnetic field signal set; and
a current calculation module configured to calculate a live wire current and a neutral wire current based on the magnetic field signal set, and then calculate a total current based on a current direction.

Preferably, the data acquisition module includes a signal acquisition unit;
the signal acquisition unit is configured to, via Hall effect sensors around a live wire and a neutral wire, sense magnetic fields generated by current flow in real time; and each of the Hall effect sensors is configured to sense changes in surrounding magnetic fields based on intensity of the current flow and convert magnetic field signals into voltage signals, and
an acquisition process is periodic and performed based on the preset sampling frequency, and the acquired voltage signals are respectively labeled as a live wire magnetic field signal Fm and a neutral wire magnetic field signal Zm.

Preferably, the data acquisition module further includes a signal pre-amplification unit;
the signal pre-amplification unit is configured to increase, based on gain amplification, an amplitude of the acquired live wire magnetic field signal Fm and an amplitude of the acquired neutral wire magnetic field signal Zm through a gain amplification circuit; and
the amplified live wire magnetic field signal Fm and the neutral wire magnetic field signal Zm are pre-filtered by using low-pass filtering to reduce high-frequency noise interference, and the pre-filtered live wire magnetic field signal and the pre-filtered neutral wire magnetic field signal are respectively labeled as a live wire magnetic field signal Fmp and a neutral wire magnetic field signal Zmp.

Preferably, the signal processing module includes a filtering unit;
the filtering unit is configured to perform frequency-domain processing on the obtained live wire magnetic field signal Fmp and the obtained neutral wire magnetic field signal Zmp by using band-pass filtering,
a lower frequency limit and an upper frequency limit for a passband are set, to allow signals having a frequency between the lower frequency limit and the upper frequency limit to pass and suppress low-frequency drift and the high-frequency noise interference; and
through the frequency-domain processing, an effective frequency band of the signals is retained, current-related magnetic field characteristics are enhanced, and output signals outputted from the filtering unit are still labeled as the live wire magnetic field signal Fmp and the neutral wire magnetic field signal Zmp.

Preferably, the signal processing module further includes a smoothing unit;
the smoothing unit is configured to extract the live wire magnetic field signal Fmp and the neutral wire magnetic field signal Zmp from the filtering unit and perform time-domain smoothing on the live wire magnetic field signal Fmp and the neutral wire magnetic field signal Zmp based on a moving average method, where a sliding window length is set to perform average calculation on consecutive sampling points to reduce instantaneous spikes and random sampling errors and eliminate local mutations; and
output signals outputted from the smoothing unit are still labeled as the live wire magnetic field signal Fmp and the neutral wire magnetic field signal Zmp.

Preferably, the dynamic correction module includes an amplitude ratio calculation unit;
the amplitude ratio calculation unit is configured to: perform real-time amplitude detection within a time window on the live wire magnetic field signal Fmp and the neutral wire magnetic field signal Zmp, and extract and respectively label instantaneous peak magnetic field intensity of the live wire and the neutral wire within each sampling cycle as instantaneous live wire magnetic field intensity Fmi and instantaneous neutral wire magnetic field intensity Zmi; and
calculate a magnetic field amplitude ratio Beta based on a ratio of the instantaneous live wire magnetic field intensity Fmi to the instantaneous neutral wire magnetic field intensity Zmi, where the magnetic field amplitude ratio Beta reflects a relative difference in magnetic field response between the live wire and the neutral wire.

Preferably, the dynamic correction module further includes a sensitivity correction unit;
the sensitivity correction unit is configured to combine the magnetic field amplitude ratio Beta with the live wire magnetic field signal Fmp and the neutral wire magnetic field signal Zmp, and perform real-time correction on a current measurement sensitivity coefficient based on a dynamic correction method, specifically, the sensitivity correction unit is configured to:
label an initial sensitivity coefficient of the non-contact multi-wire current measurement system as an initial sensitivity coefficient Ks, and calculate a theoretical magnetic field ratio Bet0 as follows: Bet0=Ks×(Fmp/Zmp);
calculate a deviation value between the actually measured magnetic field amplitude ratio Beta and the theoretical magnetic field ratio Bet0, and label the deviation value as an amplitude ratio deviation Delb wherein: Delb=Beta-Bet0;
calculate a sensitivity correction factor based on a deviation amount when the amplitude ratio deviation Delb exceeds a preset tolerance threshold, where the sensitivity correction factor is a correction factor Kc, and is calculated as follows: Kc=1+ (Delb/Beta); and
update the initial sensitivity coefficient Ks to Ks×Kc based on the calculated correction factor Kc;
the non-contact multi-wire current measurement system is configured to repeatedly calculate the amplitude ratio deviation Delb and update the sensitivity coefficient Ks within each sampling cycle, perform continuous correction until the amplitude ratio deviation Delb converges within the preset tolerance threshold, and label the obtained sensitivity coefficient Ks as a correction coefficient Kadj.

Preferably, the dynamic correction module further includes a correction signal generation unit;
the correction signal generation unit is configured to extract the correction coefficient Kadj, the live wire magnetic field signal Fmp, and the neutral wire magnetic field signal Zmp, and then perform amplitude correction on the live wire magnetic field signal Fmp and the neutral wire magnetic field signal Zmp based on a sensitivity weighting method, to generate a corrected live wire magnetic field signal Fmc and a corrected neutral wire magnetic field signal Zmc;
the corrected live wire magnetic field signal Fmc is calculated as follows:

$$Fmc = Fpm \times Kadj ;$$

the corrected neutral wire magnetic field signal Zmc is calculated as follows:

$$Zmc = Zmp \times Kadj ;$$

the corrected live wire magnetic field signal Fmc and the corrected neutral wire magnetic field signal Zmc are integrated to form the magnetic field signal set Mset.

Preferably, the current calculation module includes a current inversion calculation unit;
the current inversion calculation unit is configured to analyze, based on a magnetic field inversion calculation method, a magnetic flux change using the corrected live wire magnetic field signal Fmc and the corrected neutral wire magnetic field signal Zmc in the magnetic field signal set Mset, and calculate current values in corresponding wires, to obtain a live wire current Ifire and a neutral wire current Izero;
the live wire current Ifire is calculated as follows: Ifire=μ×(Fmc/Rf); and
the neutral wire current Izero is calculated as follows: Izero=μ×(Zmc/Rz), where
μ represents a magnetic permeability parameter, and Rf and Rz respectively represent equivalent magnetic field path coefficients for the live wire and the neutral wire.

Preferably, the current calculation module further includes a current synthesis and determining unit;
the current synthesis and determining unit is configured to calculate, for the obtained live wire current Ifire and the obtained neutral wire current Izero, a relative phase difference based on a current direction determining method and determine a flow direction relationship between the obtained live wire current Ifire and the obtained neutral wire current Izero;
the live wire current Ifire and the neutral wire current Izero in opposite phases are determined as currents from a same circuit, and a total current Itotal is calculated in a differential form: total current Itotal=|Ifire−Izero|;
the live wire current Ifire and the neutral wire current Izero in a same phase are determined as currents from different circuits, a total current Itotal is calculated in an additive form: total current Itotal=|Ifire+Izero|; and
the calculated total current Itotal represents a multi-wire measurement result of the non-contact multi-wire current measurement system.

The non-contact multi-wire current measurement system provided in the present disclosure has the following beneficial effects:
(1) The live wire magnetic field signal and the neutral wire magnetic field signal are synchronously acquired in real time based on the preset sampling frequency, to achieve highly time-synchronized magnetic field acquisition without damaging a cable structure, avoiding a phase misalignment problem caused by a traditional clamp sensor under a multi-wire interference condition. The magnetic field amplitude ratio is calculated in real time, sensitivity is automatically adjusted based on a coupling deviation due to a difference in wire diameter and insulation layer, the self-corrected magnetic field signal set is generated, the live wire current and the neutral wire current are calculated, and the total current is obtained by further combining the live wire current with the neutral wire current. This non-contact vector-based calculation method avoids wire heating, voltage drop, and safety risks associated with direct series measurement, achieving accurate inversion of current direction and amplitude in a plurality of wires without damaging insulation or altering circuit topology.
(2) The live wire magnetic field signal Fmp and the neutral wire magnetic field signal Zmp are extracted by using the amplitude ratio calculation method within each sampling cycle to obtain the instantaneous live wire magnetic field intensity Fmi and the instantaneous neutral wire magnetic field intensity Zmi, and the magnetic field amplitude ratio Beta is calculated. This calculation not only reflects a real-time symmetry difference in magnetic response of the live wire and the neutral wire, but also provides the non-contact multi-wire current measurement system with real-time data for dynamically judging a sensitivity deviation.

Subsequently, deviation analysis is performed by the sensitivity correction unit by comparing the magnetic field amplitude ratio Beta with the theoretical magnetic field ratio Bet0, the amplitude ratio deviation Delb is calculated, and the sensitivity correction factor Kc is calculated based on the amplitude ratio deviation Delb to update the sensitivity coefficient Ks of the non-contact multi-wire current measurement system in real time, and finally the correction coefficient Kadj is obtained under iterative convergence conditions. A self-correction closed loop is formed based on deviation feedback in this process, enabling the non-contact multi-wire current measurement system to maintain consistent current response sensitivity under different conductor types, insulation thicknesses, and even temperature conditions. The correction coefficient Kadj is applied to the live wire magnetic field signal Fmp and the neutral wire magnetic field signal Zmp to generate the corrected live wire magnetic field signal Fmc and the corrected neutral wire magnetic field signal Zmc, which form the magnetic field signal set Mset. This provides data input with high physical consistency for subsequent current calculations. Consequently, the non-contact multi-wire current measurement system can maintain an accurate magnetic field-current correspondence in complex cable environments characterized by multi-conductor coupling and severe signal mutual inductance.
(3) The corrected live wire magnetic field signal Fmc and the corrected neutral wire magnetic field signal Zmc in the magnetic field signal set Mset are respectively converted into the live wire current Ifire and the neutral wire current Izero. The magnetic permeability parameter u and the equivalent magnetic field path coefficients Rf, Rz are introduced in this inversion calculation process, achieving a linear analysis from magnetic field intensity to current amplitude. This allows the non-contact multi-wire current measurement system to automatically correct an attenuation deviation of the magnetic flux density based on an actual spatial relationship between the sensor and the wire. In addition, relative phases between the live wire current Ifire and the neutral wire current Izero are calculated in real time by using a current direction determining method, to determine whether the currents belong to the same circuit based on the phase relationship. Differences in current direction can be automatically identified by the non-contact multi-wire current measurement system by using the differentiated calculation method, thereby effectively distinguishing scenarios such as leakage currents, backed currents, or multi-branch superposition.

### BRIEF DESCRIPTION OF THE DRAWINGS

FIG. 1 is a schematic block diagram of a non-contact multi-wire current measurement system according to the present disclosure; and

FIG. 2 is a schematic diagram of a sensitivity correction iterative convergence behavior.

### DETAILED DESCRIPTION OF THE EMBODIMENTS

The technical solutions in the embodiments of the present disclosure are clearly and completely described below with reference to the accompanying drawings in the embodiments of the present disclosure. Apparently, the described embodiments are merely a part rather than all of the embodiments of the present disclosure. All other embodiments derived from the embodiments in the present disclosure by a person of ordinary skill in the art without creative efforts should fall within the protection scope of the present disclosure.

### Embodiment 1

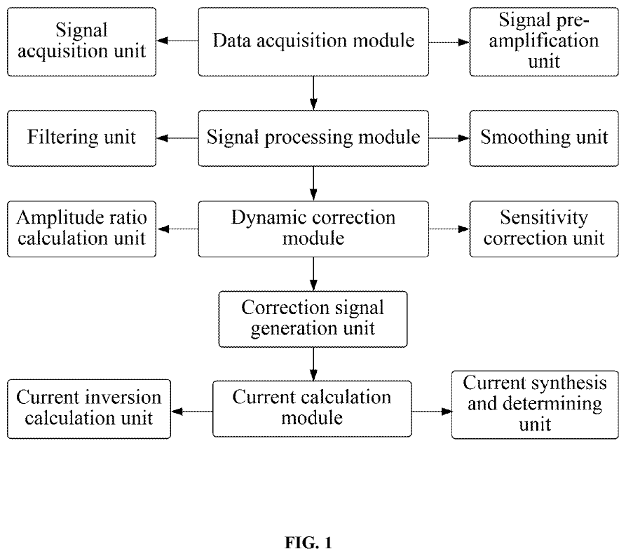

The present disclosure provides a non-contact multi-wire current measurement system. As shown in FIG. 1, the non-contact multi-wire current measurement system includes a data acquisition module, a signal processing module, a dynamic correction module, and a current calculation module.

The data acquisition module is configured to perform real-time acquisition on a live wire magnetic field signal and a neutral wire magnetic field signal based on a preset sampling frequency.

The signal processing module is configured to perform filtering and smoothing on the live wire magnetic field signal and the neutral wire magnetic field signal to obtain a processed re-labeled live wire magnetic field signal and a processed re-labeled neutral wire magnetic field signal.

The dynamic correction module is configured to calculate a magnetic field amplitude ratio in real time based on the processed re-labeled live wire magnetic field signal and the processed re-labeled neutral wire magnetic field signal, dynamically adjust measurement sensitivity based on the magnetic field amplitude ratio, and then calculate a magnetic field signal set.

The current calculation module is configured to calculate a live wire current and a neutral wire current based on the magnetic field signal set, and then calculate a total current based on a current direction.

In this embodiment, the live wire magnetic field signal and the neutral wire magnetic field signal are synchronously acquired by the data acquisition module in real time based on the preset sampling frequency, to achieve highly time-synchronized magnetic field acquisition without damaging a cable structure, avoiding a phase misalignment problem caused by a traditional clamp sensor under a multi-wire interference condition. Noise suppression and fluctuation balance are performed by the signal processing module on a raw magnetic field signal during the filtering and smoothing stage. This provides a stable input basis for subsequent calculations, thereby avoiding non-linear distortion caused by complex electromagnetic environments or sampling variations.

Based on this, the magnetic field amplitude ratio is calculated by the dynamic correction module in real time. The sensitivity is automatically adjusted based on coupling deviations introduced by variations in wire diameter and insulation thickness, generating a self-corrected magnetic field signal set, and allowing the non-contact multi-wire current measurement system to maintain a uniform sensitivity response even when wires of different specifications are mixed. For example, inside an electrical control cabinet, inconsistent wire diameters or varying insulation thickness often lead to deviations in magnetic field signal amplitude under the same current conditions. The non-contact multi-wire current measurement system achieves automatic compensation by dynamically adjusting the sensitivity coefficient, thereby ensuring consistency and comparability in current measurement results.

Finally, the live wire current and the neutral wire current are calculated by the current calculation module based on the magnetic field signal set, and are further combined to obtain the total current. Wire heating, voltage drop, and safety risks associated with direct series measurement can be avoided by using the non-contact vector-based calculation method, achieving accurate inversion of current direction and amplitude in a plurality of wires without damaging insulation or altering circuit topology. Overall, current measurement accuracy, mounting flexibility, and long-term stability in complex wiring environments are remarkably improved by the non-contact multi-wire current measurement, providing a more reliable technical basis for energy consumption monitoring, leakage detection, and electrical safety management on an industrial site.

### Embodiment 2

Specifically, the data acquisition module includes a signal acquisition unit.

The signal acquisition unit is configured to, via Hall effect sensors around a live wire and a neutral wire, sense magnetic fields generated by current flow in real time. Each of the Hall effect sensors is configured to sense changes in surrounding magnetic fields based on intensity of the current flow and convert magnetic field signals into voltage signals.

An acquisition process is periodic and performed based on the preset sampling frequency, to ensure that magnetic field fluctuations caused by current variations are captured within each electrical cycle. The acquired voltage signals are respectively labeled as a live wire magnetic field signal Fm and a neutral wire magnetic field signal Zm.

The live wire magnetic field signal Fm is a magnetic field intensity signal around the live wire that is acquired by the Hall effect sensor in real time, and is directly correlated with variations in the live wire current.

The neutral wire magnetic field signal Zm is a magnetic field intensity signal around the neutral wire that is acquired by the Hall effect sensor in real time, and is directly correlated with variations in the neutral wire current.

The data acquisition module further includes a signal pre-amplification unit.

The signal pre-amplification unit is configured to increase, based on a gain amplification method, an amplitude of the acquired live wire magnetic field signal Fm and an amplitude of the acquired neutral wire magnetic field signal Zm through a gain amplification circuit, to ensure signal strength to be sufficiently high, and make the amplitude of the signal be adequate for subsequent processing.

The amplified live wire magnetic field signal Fm and the neutral wire magnetic field signal Zm are pre-filtered by using a low-pass filtering method to reduce high-frequency noise interference, and ensure stability and accuracy of the signals in a transmission process. The pre-filtered live wire magnetic field signal and the pre-filtered neutral wire magnetic field signal are respectively labeled as a live wire magnetic field signal Fmp and a neutral wire magnetic field signal Zmp for being transmitted to the signal processing module.

In the gain amplification method, the amplitude of the signal is increased through a gain circuit (for example, an operational amplifier) to ensure distortion-free signal transmission. Strength of the signal can be enhanced through the gain amplification method, maintaining effectiveness of the signal throughout the transmission process.

In the low-pass filtering method, high-frequency noise is removed by a low-pass filter from the signal, ensuring purity and accuracy of the signal. The low-pass filter is configured to allow low-frequency signals to pass through, thereby filtering high-frequency components and improving signal quality.

In this embodiment, the magnetic fields generated by the current flow can be sensed by the Hall effect sensor arranged around the live and neutral wires in real time without damaging the insulation layer, and magnetic field variations are directly converted into voltage signals, avoiding reading distortions, due to spatial interference or magnetic flux superposition, in the traditional clamp current sensor in high-density wires. Current fluctuations are completely captured in a periodic sampling manner, enabling the non-contact multi-wire current measurement system to accurately reconstruct true current characteristics under varying periodic loads. For example, in a motor control circuit in which a rapid current pulsation occurs during startup or braking, the complete magnetic field variation within each sampling cycle can be recorded by the non-contact multi-wire current measurement system, preventing transient currents from being ignored.

Subsequently, the amplitude of the live wire magnetic field signal Fm and the amplitude of the neutral wire magnetic field signal Zm are increased by the signal pre-amplification unit by using the gain amplification method, making the signals have sufficient strength to withstand transmission losses before entering subsequent modules. High-frequency noises in the amplified signals are removed by using the low-pass filtering method, and are subsequently re-labeled as a processed live wire magnetic field signal Fmp and a processed neutral wire magnetic field signal Zmp, to maintain waveform stability and amplitude accuracy in the transmission process, thereby reducing random errors caused by factors like poor cable shielding and ambient electromagnetic interference. For example, in power distribution cabinets or factory power lines, when transient high-frequency electromagnetic interference is generated during high-power equipment startup, noise components can be effectively isolated through low-pass filtering. Consequently, frequency band information related to actual current changes are retained in the live wire magnetic field signal Fm and the neutral wire magnetic field signal Zm.

Overall, a comprehensive pre-processing chain from magnetic field signal induction, amplification, and filtering to standardized output is implemented by the data acquisition module at a front end of signal acquisition, significantly enhancing an ability of the multi-wire non-contact measurement system to resolve weak magnetic fields and adaptability to environments with strong electromagnetic interference. As a result, precise calculations can be performed based on high-quality input in subsequent signal processing and dynamic correction stages. The multi-wire non-contact measurement system is suitable for complex electrical scenarios with strong interference, dense wires, and a significant ambient temperature difference on an industrial site, maintaining measurement accuracy and stability during long-term, and continuous operation.

### Embodiment 3

Specifically, the signal processing module includes a filtering unit.

The filtering unit is configured to perform frequency-domain processing on the obtained live wire magnetic field signal Fmp and the obtained neutral wire magnetic field signal Zmp by using a band-pass filtering method.

A lower frequency limit and an upper frequency limit for a passband are set, to allow signals having a frequency between the lower frequency limit and the upper frequency limit to pass and suppress low-frequency drift and the high-frequency noise interference.

Through the frequency-domain processing, an effective frequency band of the signals is retained, current-related magnetic field characteristics are enhanced, and output signals outputted from the filtering unit are still labeled as the live wire magnetic field signal Fmp and the neutral wire magnetic field signal Zmp.

In the band-pass filtering method, effective signals are effectively retained by defining a specific passband frequency range, and low-frequency electromagnetic drift and high-frequency noise interference are filtered, ensuring that the spectrum of the magnetic field signal is concentrated within an operational current bandwidth, and enhancing signal purity and accuracy in subsequent processing.

The signal processing module further includes a smoothing unit.

The smoothing unit is configured to extract the live wire magnetic field signal Fmp and the neutral wire magnetic field signal Zmp from the filtering unit and perform time-domain smoothing on the live wire magnetic field signal Fmp and the neutral wire magnetic field signal Zmp based on a moving average method, where a sliding window length is set to perform average calculation on consecutive sampling mutations, and making a signal curve more continuous and stable.

Output signals outputted from the smoothing unit are still labeled as the live wire magnetic field signal Fmp and the neutral wire magnetic field signal Zmp.

In the moving average method, an average of a signal sequence is calculated within a preset sampling window to reduce short-term variance and transient noise, thereby smoothening fluctuations in the magnetic field signal, improving temporal continuity and phase stability, and allowing the signal to more accurately reflect a current change trend.

In this embodiment, a passband range of the signal is defined by using the band-pass filtering, allowing only the spectral components directly related to current variations to pass through, and precisely filtering out low-frequency magnetic drift and high-frequency electromagnetic noise. This enables the system to remain focused on the effective current frequency band even in complex electromagnetic environments For example, in power control circuits or servo driver application scenarios in which environmental interference may include power frequency noise, high-frequency switching harmonics from inverters, or sensed coupling noise, signals outside an operational bandwidth can be effectively removed through the band-pass filtering, ensuring that the processed live wire magnetic field signal Fmp and the processed neutral wire magnetic field signal Zmp retain only key frequency bands that reflect load current changes, and avoiding accumulation of subsequent correction errors.

Subsequently, a rolling average calculation is performed, based on the moving average method, by the smoothing unit on the processed live wire magnetic field signal Fmp and the processed neutral wire magnetic field signal Zmp in time domain, thereby reducing instantaneous spikes and random jitter, and resulting in a more continuous and stable signal curve. Through the processing, time consistency and phase stability of the signals are improved, ensuring high traceability even under rapidly changing current conditions. For example, in a numerical-control machine tool or a variable-frequency air conditioning system, currents have spike fluctuations during load switching or power adjustment. Without smoothing, significant volatility may be caused in the calculated magnetic field amplitude ratio Beta, adversely affecting the stability of the automatic sensitivity correction. After time-domain smoothing is performed, the system can consistently capture a true current change trend, preventing transient interference from misleading an iterative direction of the dynamic correction module.

In conclusion, a joint optimization of “frequency-domain purification and time-domain balancing” can be completed by the signal processing module before the signals enter the calculation stage. In this way, the live wire magnetic field signal Fmp and the neutral wire magnetic field signal Zmp achieve both high purity and high stability in both the frequency and time domains. This not only effectively enhances the consistency of the response of the magnetic field signal to current changes but also ensures a more precise and reliable input baseline for subsequent dynamic sensitivity correction and current inversion calculation, and is especially suitable for industrial electrical system environments with parallel multi-load operation, frequent switching, or strong interference.

### Embodiment 4

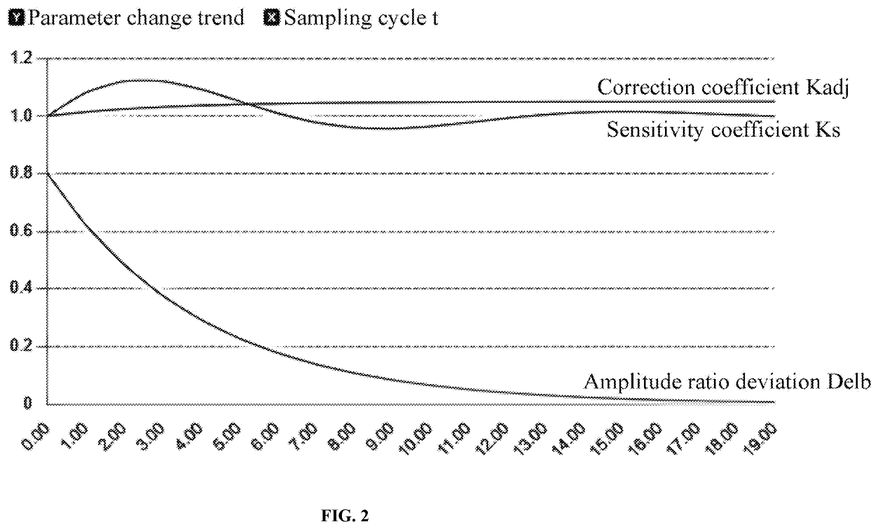

As shown in FIG. 1 and FIG. 2, specifically, the dynamic correction module includes an amplitude ratio calculation unit.

The amplitude ratio calculation unit is configured to: perform, based on an amplitude ratio calculation method, real-time amplitude detection within a time window on the live wire magnetic field signal Fmp and the neutral wire magnetic field signal Zmp, and extract and respectively label instantaneous peak magnetic field intensity of the live wire and the neutral wire within each sampling cycle as instantaneous live wire magnetic field intensity Fmi and instantaneous neutral wire magnetic field intensity Zmi; and

calculate a magnetic field amplitude ratio Beta based on a ratio of the instantaneous live wire magnetic field intensity Fmi to the instantaneous neutral wire magnetic field intensity Zmi, reflecting a relative difference in magnetic field response between the live wire and the neutral wire and being a key input parameter for dynamic correction.

The instantaneous live wire magnetic field intensity Fmi is obtained by extracting peak magnetic field intensity from the live wire magnetic field signal Fmp within each sampling cycle, reflecting an immediate magnetic field amplitude generated by current variations in a live wire conductor.

The instantaneous neutral wire magnetic field intensity Zmi is obtained by extracting peak magnetic field intensity from the neutral wire magnetic field signal Zmp within each sampling cycle, reflecting an immediate magnetic field amplitude generated by current variations in a neutral wire conductor.

The amplitude ratio calculation method is used to calculate the magnetic field amplitude ratio Beta based on the ratio of the live wire instantaneous magnetic field intensity Fmi to the neutral wire instantaneous magnetic field intensity Zmi, is used to quantitatively describe a magnetic response difference between the live and neutral wires, enabling dynamic tracking of magnetic field variations of the live and neutral wires under various current-carrying conditions, and providing foundational data for system sensitivity correction.

The dynamic correction module further includes a sensitivity correction unit.

The sensitivity correction unit is configured to combine the magnetic field amplitude ratio Beta with the live wire magnetic field signal Fmp and the neutral wire magnetic field signal Zmp, and perform real-time correction on a current measurement sensitivity coefficient based on a dynamic correction method.

Specifically, an initial sensitivity coefficient of the non-contact multi-wire current measurement system is labeled as an initial sensitivity coefficient Ks to calculate a theoretical magnetic field ratio, and the theoretical magnetic field ratio is denoted as Bet0, and is calculated as follows: Bet0=Ks×(Fmp/Zmp).

Then, a deviation value between an actually measured magnetic field amplitude ratio Beta and the theoretical magnetic field ratio Bet0 is calculated, and the deviation value is labeled as an amplitude ratio deviation Delb, and is calculated as follows: Delb=Beta−Bet0.

When the amplitude ratio deviation Delb exceeds a preset tolerance threshold, a sensitivity correction factor is calculated based on a deviation amount, where the sensitivity correction factor is a correction factor Kc, and is calculated as follows: Kc=1+(Delb/Beta).

Based on the calculated correction factor Kc, the initial sensitivity coefficient Ks of the non-contact multi-wire current measurement system is updated to Ks×Kc.

The non-contact multi-wire current measurement system is configured to repeatedly calculate the amplitude ratio deviation Delb and update the sensitivity coefficient Ks within each sampling cycle, perform continuous correction until the amplitude ratio deviation Delb converges within the preset tolerance threshold, and label the obtained sensitivity coefficient Ks as a correction coefficient Kadj that represents an actual sensitivity adjustment result of the current measurement system under the current electromagnetic conditions.

The dynamic correction module further includes a correction signal generation unit.

The correction signal generation unit is configured to extract the correction coefficient Kadj, the live wire magnetic field signal Fmp, and the neutral wire magnetic field signal Zmp, and then perform amplitude correction on the live wire magnetic field signal Fmp and the neutral wire magnetic field signal Zmp based on a sensitivity weighting method, to generate a corrected live wire magnetic field signal Fmc and a corrected neutral wire magnetic field signal Zmc.

The corrected live wire magnetic field signal Fmc is calculated as follows:

$$Fmc = Fpm \times Kadj .$$

The corrected neutral wire magnetic field signal Zmc is calculated as follows: Zmc=Zmp×Kadj.

The corrected live wire magnetic field signal Fmc and the corrected neutral wire magnetic field signal Zmc that are amplitude-corrected are integrated to form the magnetic field signal set Mset that is used to describe an effective magnetic response of the system under dynamic sensitivity adjustment as an input data source for the current calculation module.

In this embodiment, the live wire magnetic field signal Fmp and the neutral wire magnetic field signal Zmp are extracted by using the amplitude ratio calculation method within each sampling cycle to obtain the live wire instantaneous magnetic field intensity Fmi and the neutral wire instantaneous magnetic field intensity Zmi, and the magnetic field amplitude ratio Beta is calculated. This calculation not only reflects a real-time symmetry difference in magnetic response of the live wire and the neutral wire, but also provides the non-contact multi-wire current measurement system with real-time data for dynamically judging a sensitivity deviation. For example, in a three-phase load, when an insulation layer thickness or a wire diameter of the live wire is large, a magnetic response amplitude of the live wire tends to be weaker than that of the neutral wire. The system can identify this imbalance through abnormal changes in the magnetic field amplitude ratio Beta, thereby providing a trigger condition for sensitivity correction.

Subsequently, deviation analysis is performed by the sensitivity correction unit by comparing the magnetic field amplitude ratio Beta with the theoretical magnetic field ratio Bet0, the amplitude ratio deviation Delb is calculated, and the sensitivity correction factor Kc is calculated based on the amplitude ratio deviation Delb to update the system sensitivity coefficient Ks in real time, and finally the correction coefficient Kadj is obtained under iterative convergence conditions. A self-correction closed loop is formed based on deviation feedback in this process, enabling the non-contact multi-wire current measurement system to maintain consistent current response sensitivity under different conductor types, insulation thicknesses, and even temperature conditions. For example, in a factory busway system in which wires are densely arranged and experience uneven temperature rise, a conductor magnetic permeability changes as a temperature increases. A traditional static correction system has sensitivity drift during high-temperature operation while the system in the present disclosure maintains correction accuracy through dynamic iterative adjustment of Kadj, thereby eliminating temperature-dependent errors.

Finally, the correction coefficient Kadj is applied by the correction signal generation unit to the live wire magnetic field signal Fmp and the neutral wire magnetic field signal Zmp to generate the corrected live wire magnetic field signal Fmc and the corrected neutral wire magnetic field signal Zmc, which form the magnetic field signal set Mset. This set reflects the effective magnetic response of the system under dynamic sensitivity compensation, and provides data input with high physical consistency for subsequent current calculations. Consequently, the non-contact multi-wire current measurement system can maintain an accurate magnetic field-current correspondence in complex cable environments characterized by multi-conductor coupling and severe signal mutual inductance. For example, in a high-density power distribution cabinet or a new energy charging pile, electromagnetic coupling between different wires often leads to accumulation of measurement errors. Magnetic field differences among a plurality of wires are corrected in real time, achieving measurement consistency and reliability under long-term continuous monitoring, and ensuring measurement stability and traceability of the entire system.

### Embodiment 5

Specifically, the current calculation module includes a current inversion calculation unit.

The current inversion calculation unit is configured to analyze, based on a magnetic field inversion calculation method, a magnetic flux change using the corrected live wire magnetic field signal Fmc and the corrected neutral wire magnetic field signal Zmc in the magnetic field signal set Mset, and calculate current values in corresponding conductors, to obtain a live wire current Ifire and a neutral wire current Izero.

The live wire current Ifire is calculated as follows: Ifire=μ×(Fmc/Rf); and

The neutral wire current Izero is calculated as: Izero=μ×(Zmc/Rz),

Herein, μ represents a magnetic permeability parameter, and represents a linear sensitivity of a non-contact sensor to a magnetic flux response. Rf and Rz respectively represent equivalent magnetic field path coefficients for the live wire and the neutral wire, and are used to correct influence of spatial distribution of wires on the magnetic flux density. Specific values of Rf and Rz are user-defined.

It should be noted that:
The magnetic field inversion calculation method is an analytical method based on a relationship between the magnetic flux density and a conductor current, and is used to convert magnetic field intensity signals into current amplitude values, achieving quantitative conversion for non-contact measurement.

The magnetic permeability parameter u reflects a proportional relationship between magnetic field signal intensity and current magnitude, and is a fixed parameter determined during system correction.

The equivalent magnetic field path coefficients Rf and Rz are used to correct magnetic field attenuation caused by a spatial arrangement difference between the live and neutral wires, ensuring consistent accuracy in current conversion across varying layout conditions.

The current calculation module further includes a current synthesis and determining unit.

The current synthesis and determining unit is configured to calculate, for the obtained live wire current Ifire and the obtained neutral wire current Izero, a relative phase difference based on a current direction determining method and determine a flow direction relationship between the obtained live wire current Ifire and the obtained neutral wire current Izero.

The live wire current Ifire and the neutral wire current Izero in opposite phases are determined as currents from a same circuit, and a total current Itotal is calculated in a differential form: total current Itotal=|Ifire−Izero|.

The live wire current Ifire and the neutral wire current Izero in a same phase are determined as currents from different circuits, a total current Itotal is calculated in an additive form: total current Itotal=|Ifire+Izero|.

The calculated total current Itotal represents a multi-wire measurement result of the non-contact multi-wire current measurement system.

In this embodiment, the corrected live wire magnetic field signal Fmc and the corrected neutral wire magnetic field signal Zmc in the magnetic field signal set Mset are respectively converted into a live wire current Ifire and a neutral wire current Izero. The magnetic permeability parameter u and the equivalent magnetic field path coefficients Rf, Rz are introduced in this inversion calculation process, achieving a linear analysis from magnetic field intensity to current amplitude. This allows the non-contact multi-wire current measurement system to automatically correct an attenuation deviation of the magnetic flux density based on an actual spatial relationship between the sensor and the wire. For example, in closely-arranged cables, relative positions of the live and neutral wires may not be symmetrical. A traditional algorithm can introduce measurement errors due to magnetic flux imbalance, and the current calculation module can still accurately obtain the actual current values through inversion after correction using equivalent path coefficients, ensuring that non-contact measurement remains consistent in magnitude with direct series measurement.

In addition, relative phases between the live wire current Ifire and the neutral wire current Izero are calculated by the current synthesis and determining unit in real time by using a current direction determining method, to determine whether the currents belong to the same circuit based on the phase relationship. When phases of the live wire current Ifire and the neutral wire current Izero are opposite, the total current Itotal=|Ifire-Izero| is obtained through differential calculation, reflecting a net current within the loop. When the phases of the live wire current Ifire and the neutral wire current Izero are the same, the total current Itotal=|Ifire+Izero| is obtained through summation calculation, and is used to identify the total current of different loops or parallel branches. Differences in current direction can be automatically identified by the non-contact multi-wire current measurement system by using the differentiated calculation method, thereby effectively distinguishing scenarios such as leakage currents, backed currents, or multi-branch superposition. In a building electrical system, when a ground fault occurs in a branch, the phases of the live wire current and the neutral wire current can shift instantaneously. An abnormal current direction can be immediately identified by the system based on the phase difference of the current calculation module, achieving an early warning function.

Overall, the current calculation module can be integrated to allow the system not only to accurately quantify conductor current in a non-contact state but also to dynamically determine a current direction and loop characteristics, achieving a “quantitative and directional” dual output at the measurement level. The total current Itotal is no longer a simple magnitude value but a comprehensive measurement that includes directional information and a phase relationship. This significantly enhance a diagnostic capability and an electrical safety assessment value of the system in a complex wiring environment. For example, in a data center busway inspection or a high-voltage power distribution system of a new energy vehicle, the current calculation module can achieve real-time identification of return currents across a plurality of paths. This effectively avoids false leakage alarms and current estimation errors, providing a reliable measurement basis for subsequent intelligent monitoring and energy consumption analysis.

Although the embodiments of the present disclosure have been illustrated and described, it should be understood that those of ordinary skill in the art may make various changes, modifications, replacements and variations to the above embodiments without departing from the principle and spirit of the present disclosure, and the scope of the present disclosure is limited by the appended claims and their legal equivalents.

What is claimed is:

1. A non-contact multi-wire current measurement system, comprising:
a data acquisition module configured to perform real-time acquisition on a live wire magnetic field signal and a neutral wire magnetic field signal based on a preset sampling frequency;
a signal processing module configured to perform filtering and smoothing on the live wire magnetic field signal and the neutral wire magnetic field signal to obtain a processed re-labeled live wire magnetic field signal and a processed re-labeled neutral wire magnetic field signal;
a dynamic correction module configured to calculate a magnetic field amplitude ratio in real time based on the processed re-labeled live wire magnetic field signal and the processed re-labeled neutral wire magnetic field signal, dynamically adjust measurement sensitivity based on the magnetic field amplitude ratio, and then calculate a magnetic field signal set; and
a current calculation module configured to calculate a live wire current and a neutral wire current based on the magnetic field signal set, and then calculate a total current based on a current direction.

2. The non-contact multi-wire current measurement system according to claim 1, wherein the data acquisition module comprises a signal acquisition unit;
the signal acquisition unit is configured to, via Hall effect sensors around a live wire and a neutral wire, sense magnetic fields generated by current flow in real time;
and each of the Hall effect sensors is configured to sense changes in surrounding magnetic fields based on intensity of the current flow and convert magnetic field signals into voltage signals, and
an acquisition process is periodic and performed based on the preset sampling frequency, and the acquired voltage signals are respectively labeled as a live wire magnetic field signal Fm and a neutral wire magnetic field signal Zm.

3. The non-contact multi-wire current measurement system according to claim 2, wherein the data acquisition module further comprises a signal pre-amplification unit;
the signal pre-amplification unit is configured to increase, based on gain amplification, an amplitude of the acquired live wire magnetic field signal Fm and an amplitude of the acquired neutral wire magnetic field signal Zm through a gain amplification circuit; and
the amplified live wire magnetic field signal and the amplified neutral wire magnetic field signal are pre-filtered by using low-pass filtering to reduce high-frequency noise interference, and the pre-filtered live wire magnetic field signal and the pre-filtered neutral wire magnetic field signal are respectively labeled as a live wire magnetic field signal Fmp and a neutral wire magnetic field signal Zmp.

4. The non-contact multi-wire current measurement system according to claim 3, wherein the signal processing module comprises a filtering unit;
the filtering unit is configured to perform frequency-domain processing on the obtained live wire magnetic field signal Fmp and the obtained neutral wire magnetic field signal Zmp by using band-pass filtering,
a lower frequency limit and an upper frequency limit for a passband are set, to allow signals having a frequency between the lower frequency limit and the upper frequency limit to pass and suppress low-frequency drift and the high-frequency noise interference; and
through the frequency-domain processing, an effective frequency band of the signals is retained, current-related magnetic field characteristics are enhanced, and output signals outputted from the filtering unit are still labeled as the live wire magnetic field signal Fmp and the neutral wire magnetic field signal Zmp.

5. The non-contact multi-wire current measurement system according to claim 4, wherein the signal processing module further comprises a smoothing unit;
the smoothing unit is configured to extract the live wire magnetic field signal Fmp and the neutral wire magnetic field signal Zmp from the filtering unit and perform time-domain smoothing on the live wire magnetic field signal Fmp and the neutral wire magnetic field signal Zmp based on a moving average method, wherein a sliding window length is set to perform average calculation on consecutive sampling mutations; and
output signals outputted from the smoothing unit are still labeled as the live wire magnetic field signal Fmp and the neutral wire magnetic field signal Zmp.

6. The non-contact multi-wire current measurement system according to claim 5, wherein the dynamic correction module comprises an amplitude ratio calculation unit;
the amplitude ratio calculation unit is configured to: perform real-time amplitude detection within a time window on the live wire magnetic field signal Fmp and the neutral wire magnetic field signal Zmp outputted from the smoothing unit, and extract and respectively label instantaneous peak magnetic field intensity of the live wire and the neutral wire within each sampling cycle as instantaneous live wire magnetic field intensity Fmi and instantaneous neutral wire magnetic field intensity Zmi; and
calculate a magnetic field amplitude ratio Beta based on a ratio of the instantaneous live wire magnetic field intensity Fmi to the instantaneous neutral wire magnetic field intensity Zmi, wherein the magnetic field amplitude ratio Beta reflects a relative difference in magnetic field response between the live wire and the neutral wire.

7. The non-contact multi-wire current measurement system according to claim 6, wherein the dynamic correction module further comprises a sensitivity correction unit;
the sensitivity correction unit is configured to combine the magnetic field amplitude ratio Beta with the live wire magnetic field signal Fmp and the neutral wire magnetic field signal Zmp outputted from the smoothing unit, and perform real-time correction on a current measurement sensitivity coefficient based on dynamic correction, specifically, the sensitivity correction unit is configured to:
label an initial sensitivity coefficient of the non-contact multi-wire current measurement system as an initial sensitivity coefficient Ks, and calculate a theoretical magnetic field ratio Bet0 as follows: Bet0=Ks×(Fmp/Zmp);
calculate a deviation value between the magnetic field amplitude ratio Beta and the theoretical magnetic field ratio Bet0, and label the deviation value as an amplitude ratio deviation Delb, wherein Delb=Beta−Bet0;
calculate a sensitivity correction factor based on a deviation amount when the amplitude ratio deviation Delb exceeds a preset tolerance threshold, wherein the sensitivity correction factor is a correction factor Kc, and is calculated as follows: Kc=1+(Delb/Beta); and
update the initial sensitivity coefficient Ks to Ks×Kc based on the calculated correction factor Kc;
the non-contact multi-wire current measurement system is configured to repeatedly calculate the amplitude ratio deviation Delb and update the sensitivity coefficient Ks within each sampling cycle, perform continuous correction until the amplitude ratio deviation Delb converges within the preset tolerance threshold, and label the obtained sensitivity coefficient Ks as a correction coefficient Kadj.

8. The non-contact multi-wire current measurement system according to claim 7, wherein the dynamic correction module further comprises a correction signal generation unit;
the correction signal generation unit is configured to extract the correction coefficient Kadj, the live wire magnetic field signal Fmp and the neutral wire magnetic field signal Zmp outputted from the smoothing unit, and then perform amplitude correction on the live wire magnetic field signal Fmp and the neutral wire magnetic field signal Zmp outputted from the smoothing unit based on a sensitivity weighting method, to generate a corrected live wire magnetic field signal Fmc and a corrected neutral wire magnetic field signal Zmc;
the corrected live wire magnetic field signal Fmc is calculated as follows: Fmc=Fmp×Kadj;
the corrected neutral wire magnetic field signal Zmc is calculated as follows:
$$Zmc = Zmp \times Kadj ;$$
and
the corrected live wire magnetic field signal Fmc and the corrected neutral wire magnetic field signal Zmc are integrated to form the magnetic field signal set Mset.

9. The non-contact multi-wire current measurement system according to claim 8, wherein the current calculation module comprises a current inversion calculation unit;
the current inversion calculation unit is configured to analyze, based on a magnetic field inversion calculation method, a magnetic flux change using the corrected live wire magnetic field signal Fmc and the corrected neutral wire magnetic field signal Zmc in the magnetic field signal set Mset, and calculate current values in corresponding wires to obtain a live wire current Ifire and a neutral wire current Izero;
the live wire current Ifire is calculated as follows: Ifire=μ×(Fmc/Rf); and
the neutral wire current Izero is calculated as follows: Izero=μ×(Zmc/Rz), wherein
μ represents a magnetic permeability parameter, and Rf and Rz respectively represent equivalent magnetic field path coefficients for the live wire and the neutral wire.

10. The non-contact multi-wire current measurement system according to claim 9, wherein the current calculation module further comprises a current synthesis and determining unit;
the current synthesis and determining unit is configured to calculate, for the obtained live wire current Ifire and the obtained neutral wire current Izero, a relative phase difference based on a current direction determining method and determine a flow direction relationship between the obtained live wire current Ifire and the obtained neutral wire current Izero;
the live wire current Ifire and the neutral wire current Izero in opposite phases are determined as currents from a same circuit, and a total current Itotal is calculated in a differential form: total current Itotal=|Ifire−Izero|;
the live wire current Ifire and the neutral wire current Izero in a same phase are determined as currents from different circuits, a total current Itotal is calculated in an additive form: total current Itotal=|Ifire+Izero|; and
the calculated total current Itotal represents a multi-wire measurement result of the non-contact multi-wire current measurement system.
